(19) United States
(12) Patent Application Publication
(10) Pub. No.: US 2008/0157353 A1
(43) Pub. Date: Jul. 3, 2008

(54) Control of Standoff Height Between Packages with a Solder-Embedded Tape

(75) Inventors: Masako Watanabe, Oita-shi (JP); Masazumi Amagai, Tsukuba-shi (JP)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/618,417

(22) Filed: Dec. 29, 2006

(51) Int. Cl. H01L 23/48

(52) U.S. Cl. 257/734

(57) ABSTRACT

A microelectronic device package interconnect for electrically connecting a plurality of substrates is provided. The microelectronic device package interconnect comprises an insulative layer positioned on a substrate, wherein the insulative layer has an opening extending through the insulative layer to the substrate. The microelectronic device package interconnect further comprises solder positioned in the opening.

### CROSS-REFERENCE TO RELATED APPLICATIONS

Not applicable

### STATEMENT REGARDING FEDERALLY SPONSORED RESEARCH OR DEVELOPMENT

Not applicable.

### REFERENCE TO A MICROFICHE APPENDIX

Not applicable.

### FIELD

The present disclosure is directed to the assembly and packaging of microelectronic devices, and more particularly, but not by way of limitation, to a microelectronic device package and method of manufacture.

### BACKGROUND

The assembly of microelectronic devices into packages suitable for use in electronic products is a long and complex process. Generally, silicon wafers undergo multiple processes to form processed semiconductor wafers that contain a plurality of microelectronic devices. The processed wafer is subsequently cut into individual devices that are further processed into packaged microelectronic devices to form the resulting packaged device. During the final assembly step, the individual devices may be mounted onto one or more assembly structures that provide electrical routing. The assembly structures include electrical sites that are used for attachment of the assembled microelectronic device package onto other microelectronic device packages, electrical boards such as a printed circuit board (PCB), or other assemblies employed in electronic-based products. The configuration of the package presents challenges in the design and manufacturing of electronic products.

In today's electronic-based products, there are many challenges associated with microelectronic device packages. One challenge is that the complexity of the package increases as the processing power and functionality of the microelectronic device increases. For example, one microelectronic device package may include a digital signal processor (DSP) while another microelectronic device package may include memory, a graphics processor, or other devices. Furthermore, the physical size of the microelectronic device packages are being reduced because there is a ongoing need to reduce the footprint of the package in products such as mobile phones, or other mobile electronic devices. The reduced size of the package also increases the complexity of the package and the packaging process. Finally, the reliability of the assembly of microelectronic devices decreases as the complexity of the package increases.

In one particularly complex package, multiple microelectronic devices are assembled into a single microelectronic device package. The microelectronic device packages may be bumped with solder balls and mounted onto other microelectronic device packages. The lower microelectronic device in the stack may be thicker than the solder balls. Such a configuration creates difficulties in the packaging process. Consequently, a need exists for an improved method of stacking a plurality of microelectronic devices together in a single package.

### SUMMARY

The present disclosure provides a microelectronic device package interconnect for electrically connecting a plurality of substrates. The microelectronic device package interconnect includes an insulative layer positioned on a substrate, wherein the insulative layer has an opening extending through the insulative layer to the substrate. The microelectronic device package interconnect further includes solder positioned in the opening.

In an embodiment, a method for manufacturing a microelectronic device package interconnect is provided. The method includes laminating an insulative layer onto a substrate, wherein the insulative layer has a plurality of openings extending through the insulative layer. The method further includes placing solder into the openings of the insulative layer.

In another embodiment, a printed circuit board (PCB) is provided. The PCB includes a substrate having a plurality of electrical contact sites and a microelectronic device package disposed over the electrical contact sites. The PCB also includes an insulative layer positioned between the substrate and the package, wherein the insulative layer has an opening. The PCB further includes a solder positioned in the opening and electrically coupling the substrate to the microelectronic device package.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1a illustrates one embodiment of a microelectronic device package interconnect according to aspects of the present disclosure.

FIG. 1b illustrates another embodiment of a microelectronic device package interconnect according to aspects of the present disclosure.

FIG. 1c illustrates another embodiment of a microelectronic device package interconnect according to aspects of the present disclosure.

FIG. 1d illustrates another embodiment of a microelectronic device package interconnect according to aspects of the present disclosure.

FIG. 1e illustrates another embodiment of a microelectronic device package interconnect according to aspects of the present disclosure.

FIG. 2a is a flow diagram of a process for manufacturing a microelectronic device package according to one embodiment of the present disclosure.

FIG. 2b is a flow diagram of another process for manufacturing a microelectronic device package according to one embodiment of the present disclosure.

FIG. 2c is a flow diagram of another process for manufacturing a microelectronic device package according to one embodiment of the present disclosure.

FIGS. 3a through 3h are cross-sectional views of manufacturing steps for forming a microelectronic device package according to one embodiment of the present disclosure.

FIG. 4a illustrates one embodiment of a microelectronic device package according to aspects of the present disclosure.

FIG. 4b illustrates another embodiment of a microelectronic device package according to aspects of the present disclosure.

FIG. 4c illustrates another embodiment of a microelectronic device package according to aspects of the present disclosure.

FIG. 5 illustrates a top view of an exemplary general-purpose printed circuit board (PCB) suitable for implementing the embodiments of the present disclosure.

### DETAILED DESCRIPTION

It should be understood at the outset that although an illustrative implementation of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

Stacking and assembling multiple microelectronic devices into a singular package poses many challenges. Interconnecting stacked packages presents a number of difficulties including the assembly and placement of die, the placement of conductive interconnects or wires, and the choice of materials used in the package. The process of forming reliable interconnects is a critical and difficult step of the assembly process.

Accordingly, the present disclosure contemplates an insulated solder ball interconnect for electrically connecting a microelectronic device package to a substrate, such as a printed circuit board (PCB) or another microelectronic device package. The insulated solder ball interconnect provides clearance between the microelectronic device package and the substrate, or another microelectronic device package. The height of the insulated solder ball interconnect is determined by the thickness of an insulative layer disposed on the microelectronic device package or the substrate prior to placement of solder ball stacks. Conventional packaging methods employ un-supported stacked solder balls placed onto the microelectronic device package which slide and contact other solder ball stacks during assembly, often resulting in non-functional microelectronic devices. The openings formed through the insulative layer maintain the vertical alignment of the solder ball stacks, and also provide electrical insulation between other solder ball stacks. Consequently, electrical shorts are substantially reduced or eliminated by the insulated solder ball interconnect.

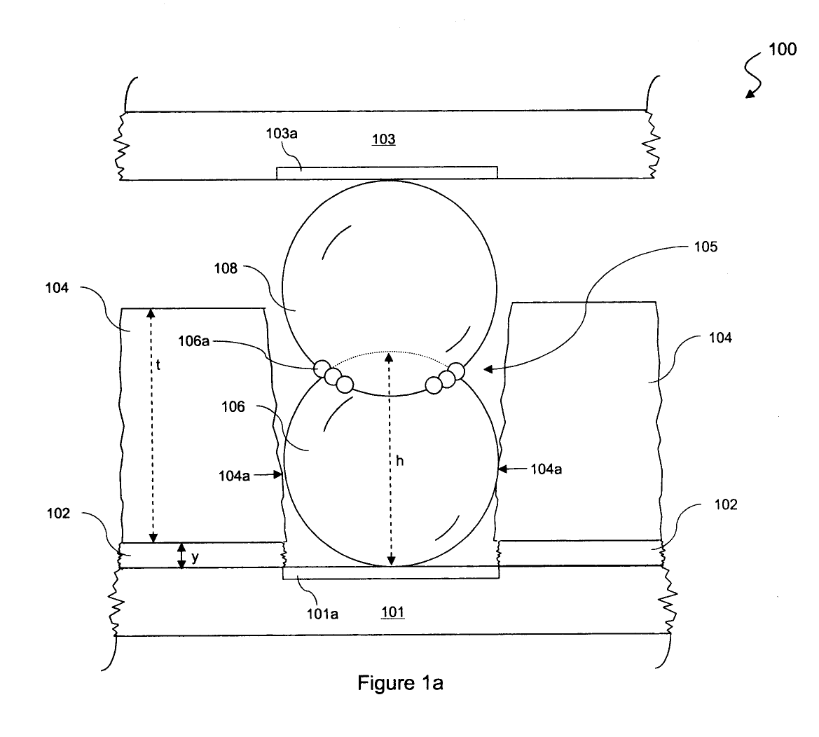

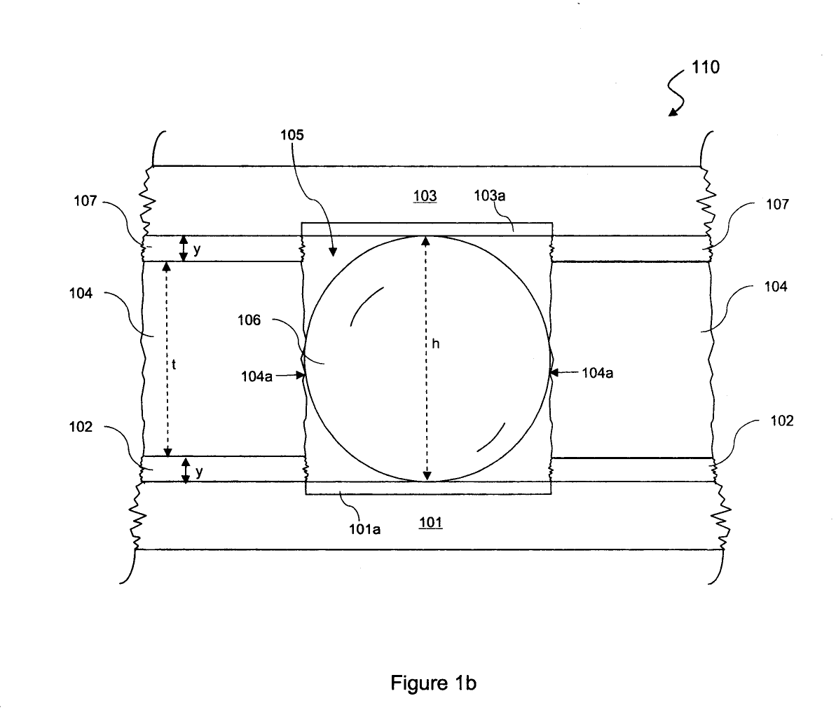

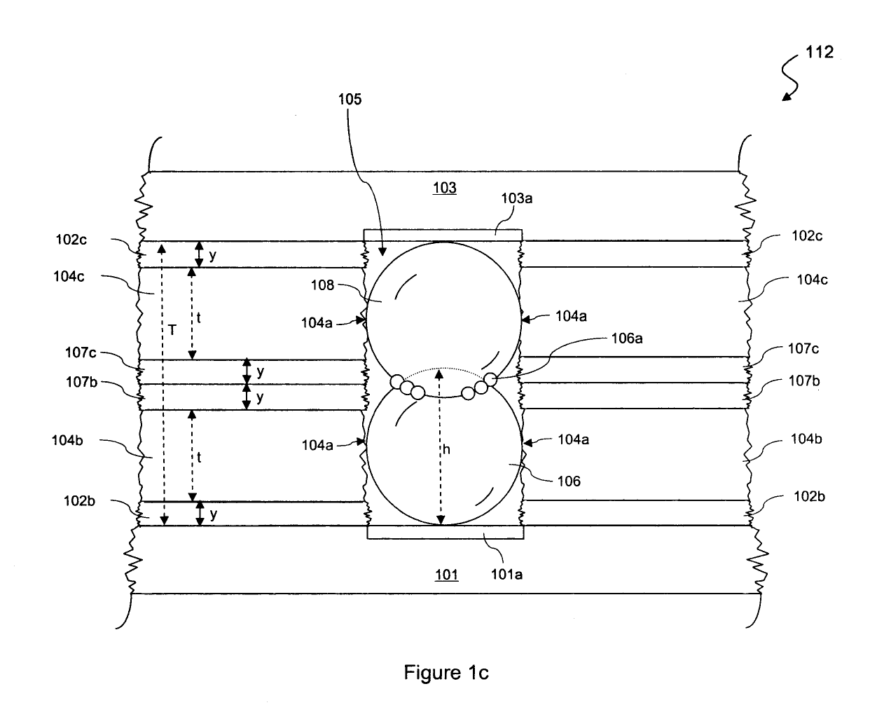

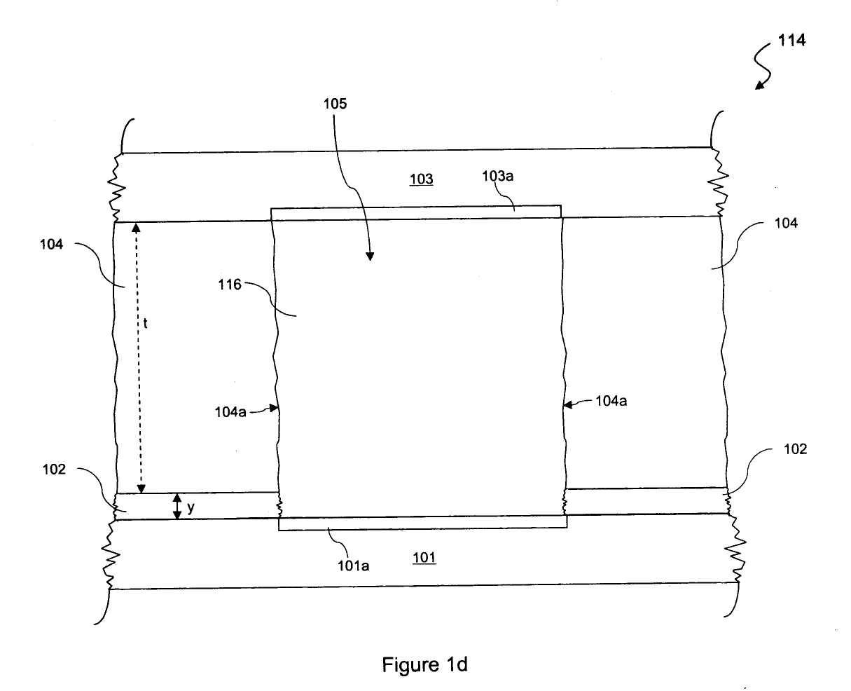

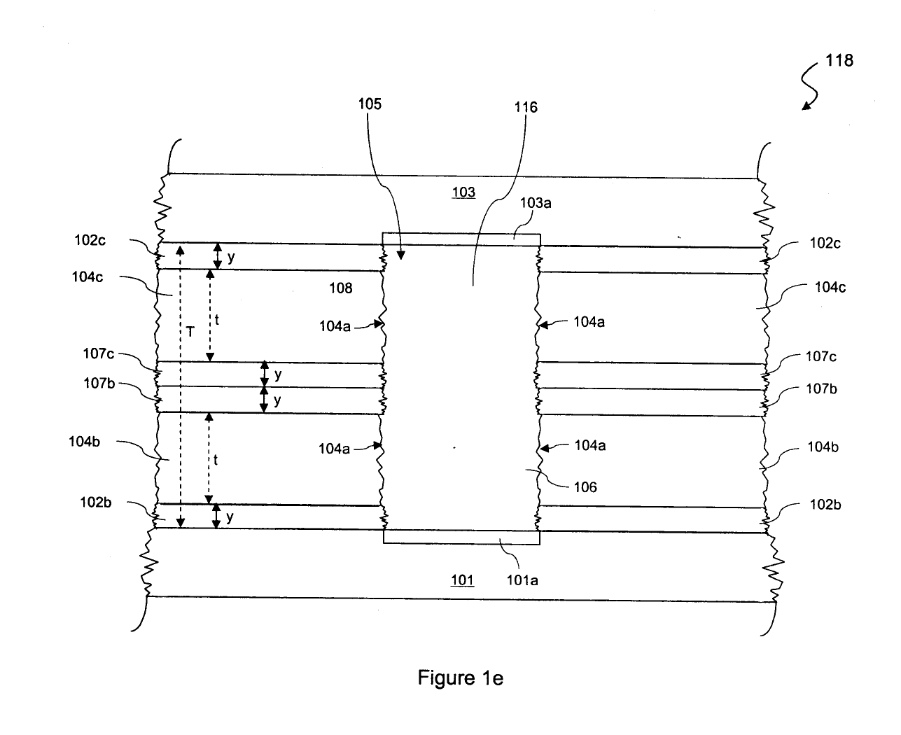

Turning now to FIG. 1a, illustrated is a solder ball interconnect 100 containing stacked solder balls 106 and 108 surrounded by an adhesive layer 102 and an insulative layer 104. The solder ball interconnect 100 provides electrical connection between two or more microelectronic device substrates 101 and 103, which may be a PCB and a microelectronic device or two or more stacked microelectronic devices, such as a package-on-package (POP) configuration. The solder ball interconnect 100 may be disposed on a first microelectronic device package substrate 101. The adhesive layer 102 connects the insulative layer 104 to the substrate 101. The adhesive layer 102 and the insulative layer 104 are patterned to form an opening 105 that extends through the insulative layer 104 and the adhesive layer 102. The opening 105 generally correlates with exposed bond pads or interconnect sites 101a and 103a on the two substrates 101 and 103. The opening 105 may be formed by milling with an excimer laser or other laser, a mechanical punch or drill, lithographic patterning and chemical or plasma etch, or other methods. The solder ball 106 is placed into the opening 105 and heated to re-flow the solder ball 106 in the opening 105 and attach the solder ball 106 to the first substrate 101. The solder ball 106 may be attached to the solder ball 108 by flux or solder paste 106a. The solder ball 106 may be made of silver, tin, copper, lead, or combinations thereof. The solder ball 106 or 108 may include a diameter h from 25 microns to 800 microns.

In an embodiment, the adhesive layer 102 and the insulative layer 104 may be a tape that is applied to the first substrate. Specifically, the adhesive layer 102 may be a thermoplastic resin or thermosetting resin that adheres the insulative layer 104 to the first substrate 101. The adhesive layer 102 may have a thickness y from 5 microns to 100 microns. The insulative layer 104 may be a polyimide or other insulative material that has a thickness t from 25 microns to 500 microns. The second microelectronic device package substrate 103 may include the solder ball 108. The solder ball 106 may be positioned in the opening 105 such that it attaches to the solder ball 108 of the second substrate 103. In an embodiment, the thickness t of the insulative layer 104 may be adjusted to change the clearance between the first substrate 101 attached to the solder ball 106 and the second substrate 103 attached to the solder ball 108. Accordingly, as the thickness t of the insulative layer 104 is changed, so may the diameter h of the solder balls 106 and 108. In another embodiment, the diameter h of the solder balls 106 and 108 may be adjusted to change the clearance between the first substrate 101 and the second substrate 103. Therefore, as the diameter h of the solder balls 106 and 108 is changed, so may the thickness t of the insulative layer 104.

In order to prevent movement of the solder balls 106 and 108 during assembly or in the final packaged device during operational thermal stress, the opening 105 may be about the diameter of the solder balls 106 and 108. Sidewalls 104a maintain the alignment of the solder balls 106 and 108 such that the alignment between the first substrate 101 and the second substrate 103 is also maintained. Such an opening configuration maintains the alignment between the first substrate 101 and the second substrate 103 before and after re-flow, which prevents the unintentional contact between two or more of the solder ball interconnects 100 during assembly. Consequently, if two or more of the solder ball interconnects 100 are positioned close together without the insulative layer 104, the solder from one interconnect 100 may undesirably contact the solder from another interconnect 100, which may cause shorting between two or more of the solder ball interconnects 100 to occur. Thus, the presence of the insulative layer 104 provides a physical electrical insulator between the two or more solder ball interconnects 100 and prevents shorting of the one or more solder ball interconnects 100.

Turning now to FIG. 1b, illustrated is an interconnect 110 containing the solder ball 106 surrounded by the adhesive layer 102 and the insulative layer 104. Like the embodiment in FIG. 1a, the solder ball 106 may form an interconnect that provides attachment of the first substrate 101 to the second substrate 103. Also like the embodiment shown in FIG. 1a, the adhesive layer 102 and the insulative layer 104 may be disposed over the first substrate 101. The adhesive layer 102 and insulative layer 104 include the opening 105 with the solder ball 106 and the second substrate 103 may be positioned over the solder ball 106. However, FIG. 1b has an optional adhesive layer 107 that is disposed over the insulative layer 104. The optional adhesive layer 107 attaches to the second substrate 103 and prevents displacement of the second substrate 103 relative to the insulative layer 104 and the first substrate 101. The optional adhesive layer 107 may consist of a thermoplastic resin or thermosetting resin to provide adhesion between the insulative layer 104 and the second substrate 103. The optional adhesive layer 107 may also include a thickness y from 5 microns to 100 microns. In an embodiment, the optional adhesive layer 107 may be employed in the solder ball interconnect 100 of FIG. 1a.

Turning now to FIG. 1c, illustrated is an interconnect 112 containing the solder balls 106 and 108 surrounded by adhesive layers 102b, 102c, 107b, and 107c and insulative layers 104b and 104c. Like the embodiment in FIG. 1a, the solder balls 106 and 108 may form an interconnect that provides attachment of the first substrate 101 to the second substrate 103. Also like the embodiment shown in FIG. 1a, the adhesive layers 102b, 102c, 107b, and 107c and the insulative layers 104b and 104c include the opening 105 positioned over the interconnect sites 101a and 103a. The adhesive layers 102b, 102c, 107b, and 107c and the insulative layers 104b and 104c may be substantially similar to the adhesive layer 102, the optional adhesive layer 107, and the insulative layer 104 of the embodiments shown in FIGS. 1a-b. The solder balls 106 and 108, the adhesive layers 102b, 102c, 107b, and 107c and the insulative layers 104b and 104c may also include a similar thicknesses or varied thicknesses. For example, the insulative layer 104b may include a thickness t of 160 microns, while the insulative layer 104c may include a thickness t of 120 microns. The adhesive layers 102b, 102c, 107b, and 107c may each include a thickness y of 5 microns, and therefore the thickness T may be 300 microns.

In an embodiment, the interconnects 100, 110, and 112 may be employed in a number of different microelectronic device packages. For, example, the interconnect 100 or 112 may be employed in an embedded package or a POP configuration, wherein the first substrate 101 may include a microelectronic device that supports telecommunication functions, while the second substrate 103 may include one or more memory-based microelectronic devices. The first substrate 101 and the second substrate 103 may be stacked and connected by the interconnect 100 or 112. The interconnect 100 or 112 also provides a pre-determined clearance between the first substrate 101 and the second substrate 103. In an embodiment, the clearance (i.e., the distance formed between the first substrate 101 and second substrate 103 by the interconnect 100, 110, and 112) is determined by the thickness t of the insulative layer 104 or the insulative layers 104b and 104c, and may be 450 microns, for example. Alternatively, the clearance may be determined by the diameter h of the solder ball 106 and 108. In contrast, the interconnect 110 may be employed in microelectronic device packages that are not limited by the clearance and include fine pitch placement with high densities of the solder balls 106. As the density of the solder balls 106 increases on the substrate 101 or 103, so does the likelihood for electrical shorting between two or more of the solder balls 106. The insulative layer 104 and the adhesive layer 102 provide electrical isolation between the two or more solder balls 106 to prevent shorting.

Of course, the solder ball interconnects 100, 110, and 112 are not to be limited to the embodiments depicted in FIGS. 1a-c, and therefore may include other configurations such as the interconnect 114 or 118 depicted in FIGS. 1d-e. The interconnect 114 includes solder 116 surrounded by the adhesive layer 102 and the insulative layer 104. The interconnect 118 includes solder 116 surrounded by the adhesive layers 102b and 102c, the optional adhesive layers 107b and 107c, and the insulative layers 104b and 104c. The solder 116 may include, for example, solder formed by solder paste or molten solder. The solder paste may include solder powder and flux. The solder powder may also include a lead-free solder such as tin, silver, and copper. The flux may include a fluid having constituents such as an adhesion-imparting agent for cleaning of the surface of the interconnect site 101a of the first substrate 101 and interconnect site 103a of the second substrate 103, a thixotropic agent to provide solder powder separation, a solvent for paste formation, and an activator for removing oxides off the surface of the interconnect sites 101a or 103a. The solder paste may be disposed into the opening 105, and subsequently reflowed at a temperature from 100 degrees C. to 200 degrees C. to form the solder 116.

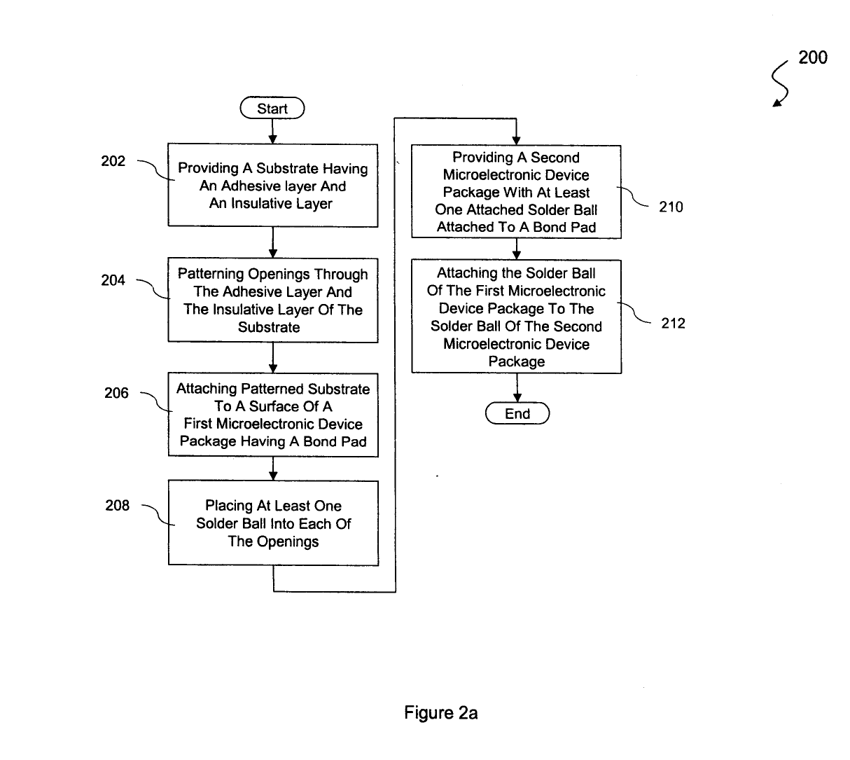

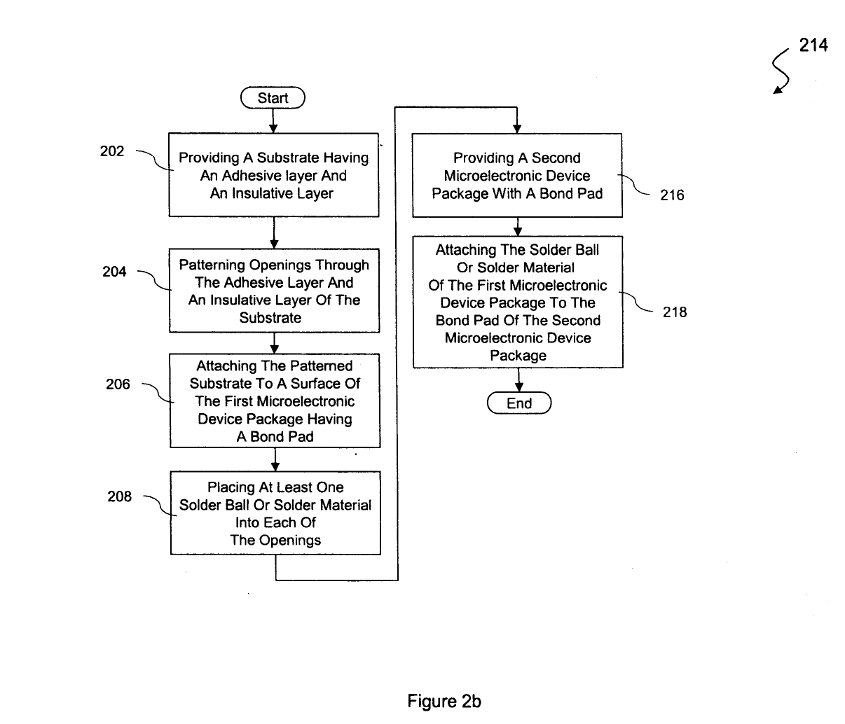

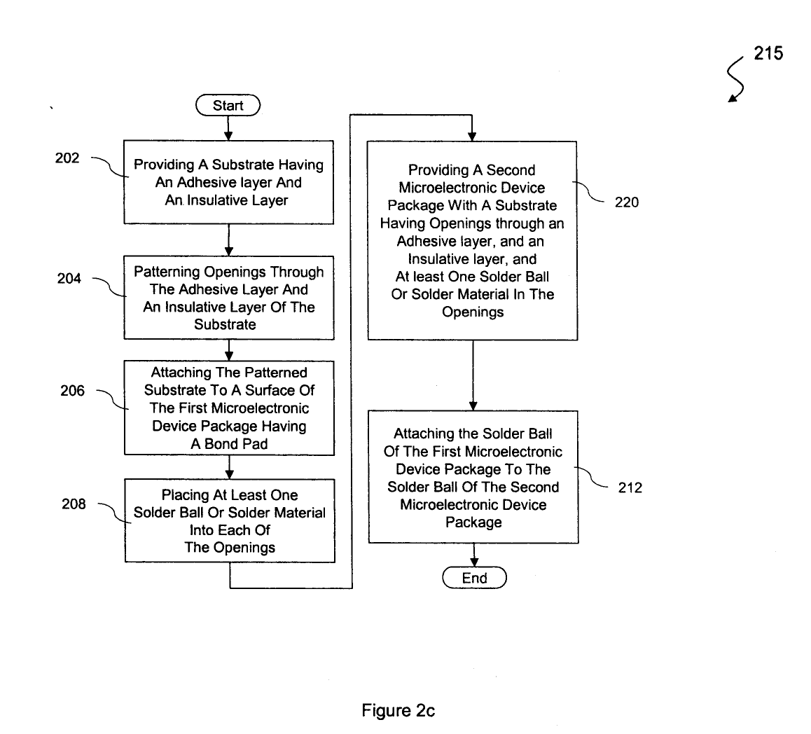

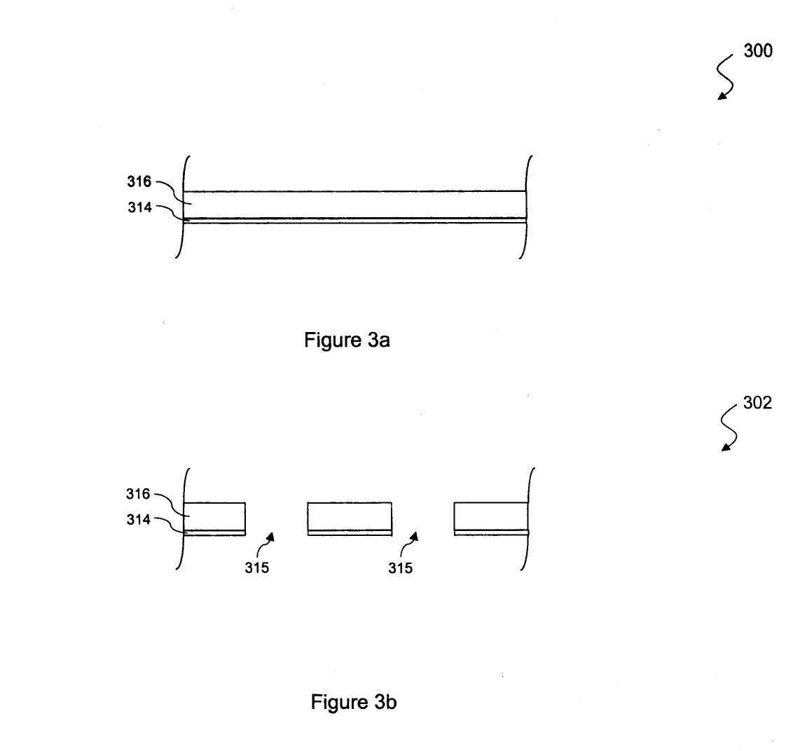

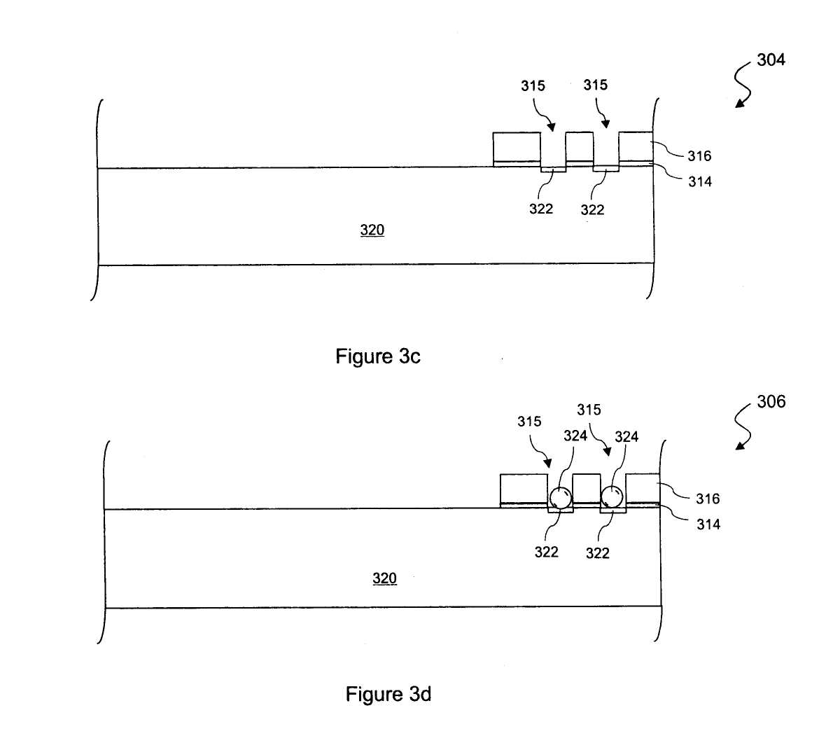

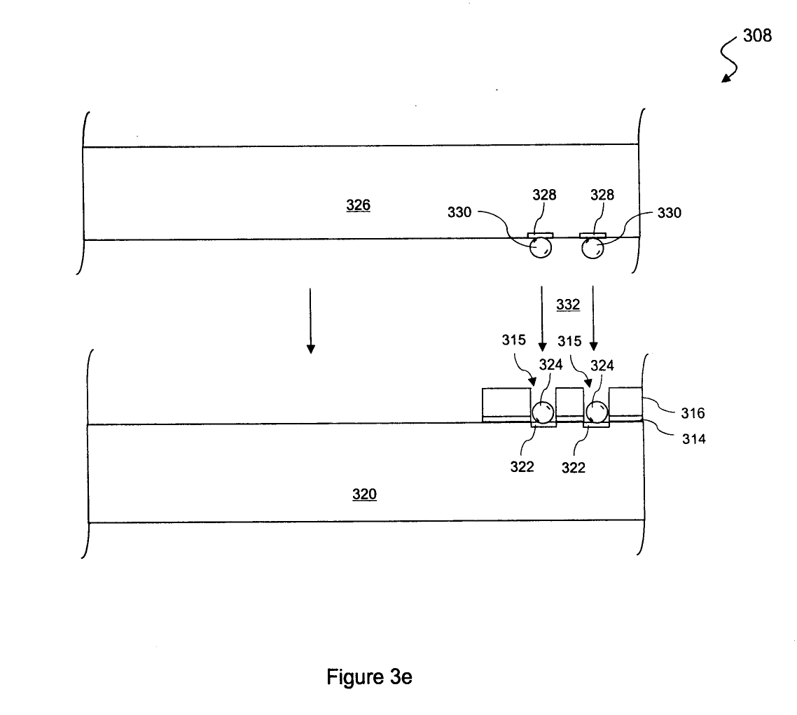

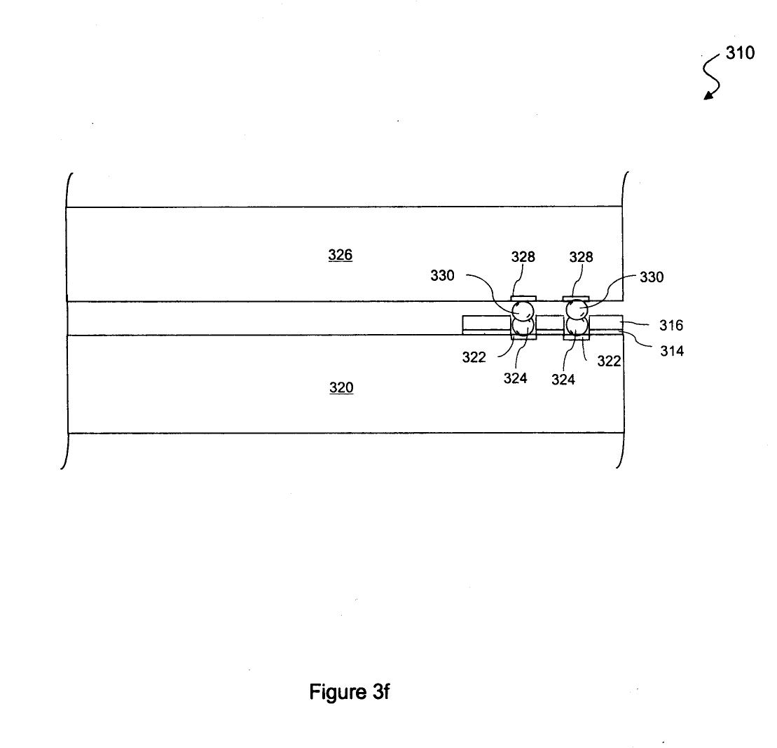

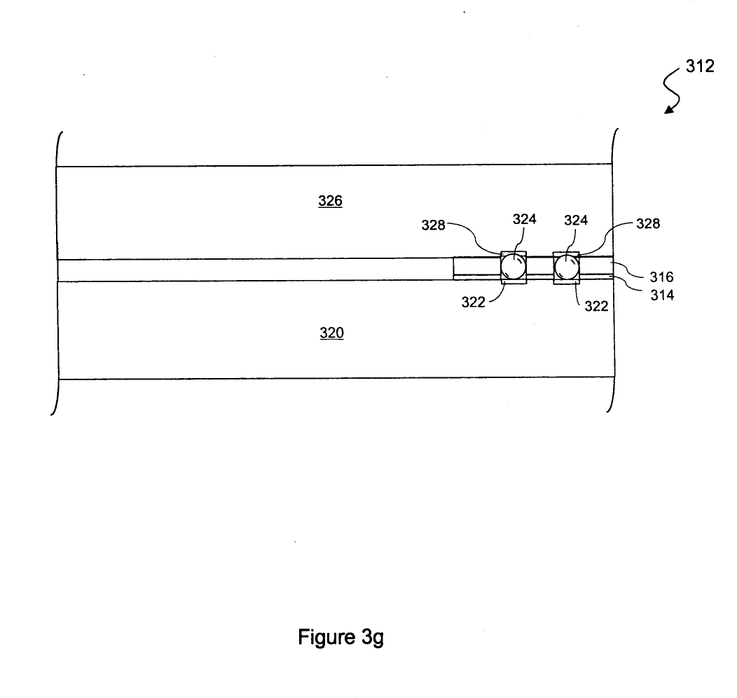

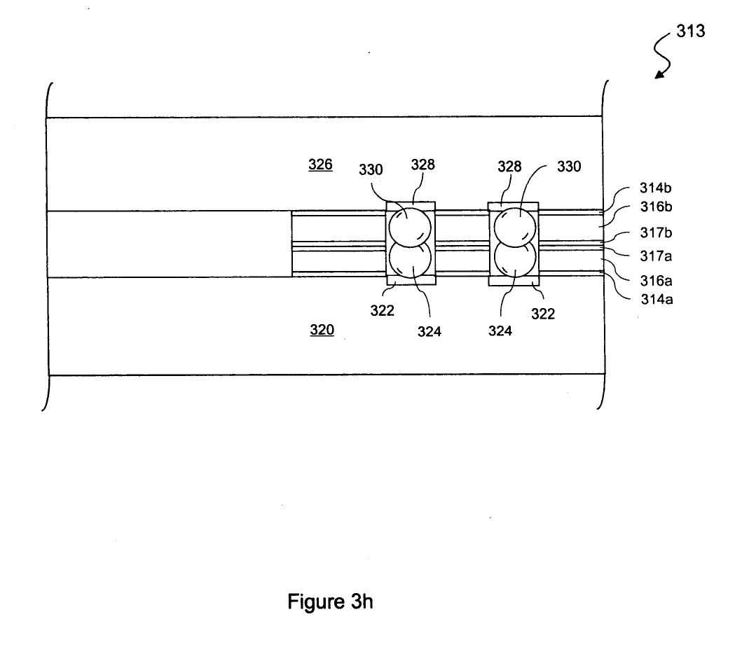

Referring to FIG. 2a, FIG. 2b, and FIG. 2c with reference to FIG. 3a through FIG. 3h, cross-sectional views 300, 302, 304, 306, 308, 310, 312, and 313 depict an embodiment of the solder ball interconnects 100, 110, and 112, and the interconnects 114 and 118. The views 300, 302, 304, 306, 308, 310, 312, and 313 illustrate assembly steps processes 200, 214, and 215 for forming the solder ball interconnects 100, 110, and 112, and the interconnects 114 and 118, and connecting to the first substrate 101 and the second substrate 103.

Turning now to FIG. 2a, one embodiment of a process 200 for forming the microelectronic device package interconnect 100 is shown. In block 202 with reference to FIG. 3a, an insulative layer 316 disposed over an adhesive layer 314 is provided. The insulative layer 316 and adhesive layer 314 may be a flat and flexible piece of tape that is applied to a substrate (not shown). The insulative layer 316 may include a polyimide or other insulative material. The adhesive layer 314 may include a thermoplastic resin or thermosetting resin. The adhesive layer 314 may be protected by a non-stick material (not shown), which may be removed prior to disposing the adhesive layer 314 and the insulative layer 316 on the surface of the substrate.

In block 204 with reference to FIG. 3b, openings 315 are formed through the insulative layer 316 and the adhesive layer 314. The insulative layer 316 is patterned to form the openings 315 that may include lines, circles, or other shapes. In an embodiment, the openings 315 may be patterned with circular features that are about the diameter of the solder balls 106 and 108. The openings 315 may be formed by milling with an excimer laser or other laser, a mechanical punch or drill, lithographic patterning and chemical or plasma etch, or other methods. The openings 315 may have a diameter from 25 microns to 800 microns. In some embodiments, the openings 315 may include two or more differing diameters. For example, a first set of the openings 315 may include a diameter of 25 microns to 200 microns, while a second set of the openings 315 may include a diameter of 200 microns to 800 microns. In this manner, the first set of the openings 315 may be used for forming input and output interconnects, and the second set of the openings 315 may be used for forming interconnects for powering or grounding a microelectronic device.

In block 206 with reference to FIG. 3c, the insulative layer 316, adhesive layer 314, and openings 315 are disposed over a first substrate 320. The adhesive layer 314 bonds the insulative layer 316 to the surface of the first substrate 320. In an embodiment, the insulative layer 316 and adhesive layer 314 are attached to the substrate 320 with a mechanical force from 0.1 gram force (gf) to 2000 gram force (gf). The mechanical force for attachment may be applied with a mechanical press or roller, for example. The openings 315 may be positioned over bond pads 322 or interconnect sites of the first substrate 320. The first substrate 320 may include a microelectronic device package, a PCB, or other electronic device substrate. The first substrate 320 may include the bond pads 322 connected to one or more microelectronic devices that may include a digital signal processor (DSP), a graphics processing unit (GPU), a central processing unit (CPU), or other devices. The devices (not shown) may be mounted on the substrate 320, and may be electrically connected to the bond pads 322 through interconnects (not shown) inside of the substrate 320. After the insulative layer 316 and adhesive layer 314 are attached, the adhesive layer 314 may be cured or heated to 150 degrees C. to bond the insulative layer 316 to the substrate 320.

In block 208 with reference to FIG. 3d, solder balls 324 are placed into the openings 315. If desired, a rosin flux may be placed over the bond pads 322 and the openings 315 prior to inserting the solder balls 324 in the openings 315. The flux may include a fluid having constituents such as an adhesive-imparting agent and an activator for removing organic residues and oxides off of the surface of the bond pads 322. After the flux is applied, the solder balls 324 are subsequently placed in the openings 315 on the bond pads 322. The flux provides solder wettability of the solder balls 324 to the bond pads 322. Solder wettability is defined as the ability of the solder balls 324 to dissolve and penetrate the surface of the bond pads 322. The molecules of the solder balls 324 and the bond pads 322 material blend to form a new alloy. The solder balls 324, the bond pads 322, the substrate 320, the adhesive layer 314, and the insulative layer 316 are heated up to 260 degrees C. to re-flow the solder balls 324 in the openings 315. Following the re-flow process, any remaining flux is removed with a solvent or other cleaning agents.

In block 210 with reference to FIG. 3e, a second substrate 326 having bond pads 328, and solder balls 330 is positioned over the first substrate 320. The second substrate 326 may include a microelectronic device package, a PCB, or other electronic device substrate. For example, the second substrate 326 may include the bond pads 328 connected to one or more microelectronic devices that include memory-based devices such as dynamic random access memory (DRAM), static random access memory (SRAM), flash memory, or other memory devices. The devices (not shown) may be mounted on the substrate 326, and may be electrically connected to the bond pads 328 through interconnects (not shown) inside of the substrate 326. Flux or solder paste may be applied to the surface of the solder balls 330. The second substrate 326 and the first substrate 320 are then pressed 332 together.

In block 212 with reference to FIG. 3f, the solder balls 330 and the solder balls 324 are attached. The solder balls 330 and 324 are heated or re-flowed up to 260 degrees C. The second substrate 326 and the first substrate 320 form interconnects or joints comprising the re-flowed solder balls 330 and 324 that are interposed by the insulative layer 316 and the adhesive layer 314. The process then ends.

Turning now to FIG. 2b, a flow diagram depicts another process 214 for forming the microelectronic device package interconnect 110 or 114. The process 214 for forming the microelectronic device package interconnect 110 or 114 depicted in FIG. 2b is substantially similar to the process 200 depicted in FIG. 2a, with the exception that after the solder balls 324 or solder 116 (as shown in FIGS. 1d-e.) is placed into the openings 315 in block 208 the second substrate 326 is provided without the solder balls 330 in blocks 216 and 218. In an embodiment, flux may be applied to the surface of the solder balls 324 or solder 116 and the bond pads 322 and 328. However, in contrast in block 208 with reference to FIG. 3d, the solder balls 324 or solder 116 are not reflowed. In blocks 216 and 218 with reference to FIG. 3g, the second substrate 326 is disposed over the first substrate 320 and the bond pads 322 and 328 are placed into contact with the solder balls 324 or solder 116. The solder balls 324 or solder 116 are subsequently heated up to 260 degrees C. to re-flow the solder material of the solder balls 324 or solder 116. A joint is formed between the bond pads 322 and 328 by the re-flow of the solder balls 324 or solder 116.

Turning now to FIG. 2c, a flow diagram depicts a process 215 for forming the microelectronic device package interconnect 112. The process 215 for forming the microelectronic device package interconnect 112 depicted in FIG. 2c is substantially similar to the process 200 depicted in FIG. 2a, with the exception that after the solder balls 324 or solder 116 (as shown in FIG. 1c.) is placed into the openings 315 in block 208 the second substrate 326 is provided with the solder balls 330, and with a second insulative layer 316b disposed over a second adhesive layer 314b is provided in block 220. In this manner, blocks 202, 204, 206, and 208 may include forming the second substrate 326 with the solder balls 330, the second insulative layer 316b, and the second adhesive layer 314b. The process 215 also includes disposing an adhesive layer 317a and 317b over a first insulative layer 316a and the second insulative layer 316b that is provided in block 202. In an embodiment, the adhesive layers 314a and 317a, and the insulative layer 316a may include a first double-sided thermoplastic resin polyimide tape having the openings 315 that may be placed over the first substrate 320. Accordingly, a second double-sided thermoplastic resin polyimide tape may be placed over the second substrate 326 having the openings 315 including the adhesive layers 314b and 317b, and the insulative layer 316b.

In block 212 with reference to FIG. 3h, the solder balls 330 and 324, and the adhesive layers 317a and 317b are attached. In an embodiment, the adhesive layers 317a and 317b are heated or cured up to 50 degrees C. The solder balls 330 and 324 are subsequently heated or reflowed up to 260 degrees C. The second substrate 326 and the first substrate 320 form interconnects or joints comprising the re-flowed solder balls 330 and 324 that are interposed by the insulative layers 316a and 316b, and the adhesive layers 314a, 314b, 317a, and 317b.

Of course it is to be understood that the blocks 202, 204, 206, and 208 may occur sequentially, or in a different order other than the process 200, 214, and 215 of FIGS. 2a-c. For example, the insulative layer 316 and adhesive layer 314 may be disposed onto the substrate 320, and subsequently patterned by a laser, chemical, or plasma etching.

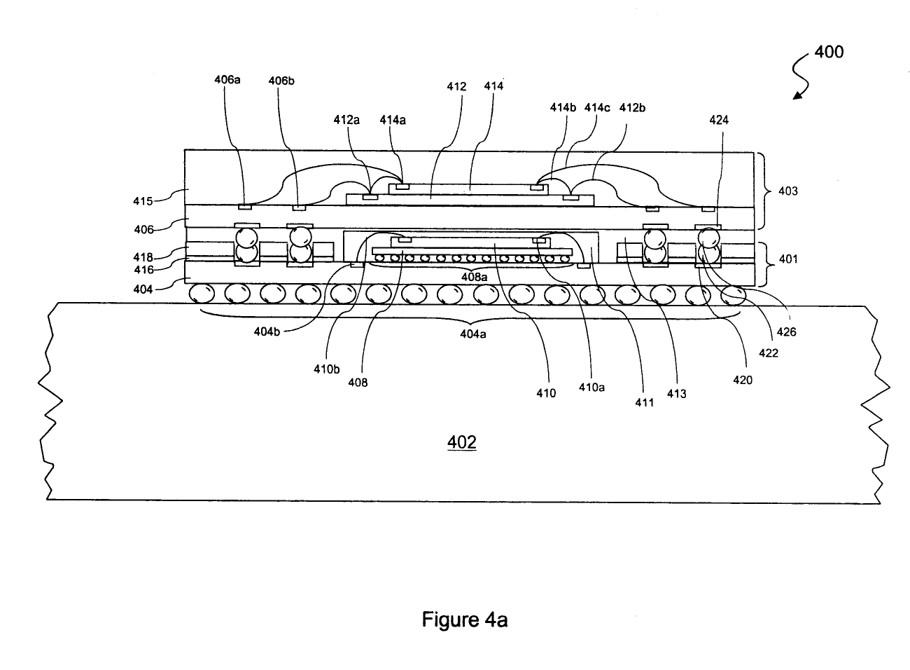

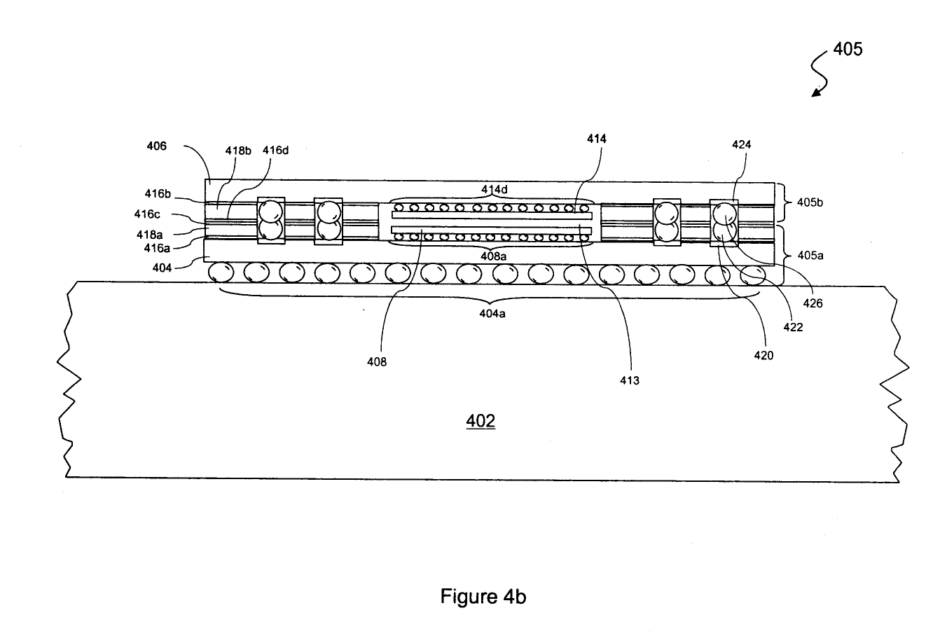

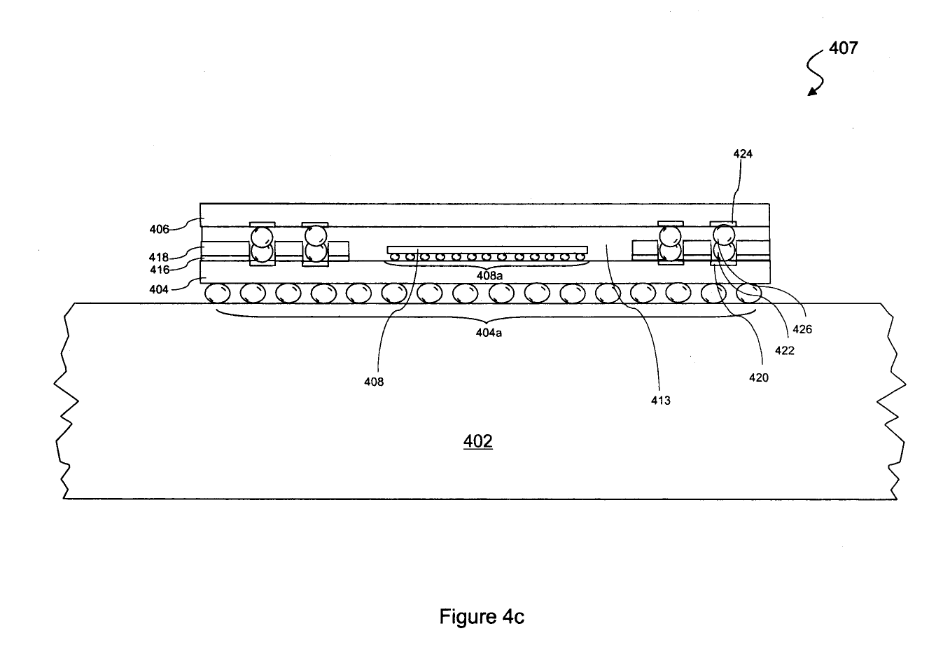

Turning now to FIG. 4a, illustrated is a microelectronic device package 400 disposed over a substrate 402. The microelectronic device package 400 includes a stack or POP configuration of microelectronic device packages 401 and 403. The package 401 includes a package substrate 404 attached to the substrate 402 by a ball grid array (BGA) 404a. The package 403 includes a package substrate 406 attached to the substrate 404 by stacked solder balls 422 and 426. In an embodiment, the solder balls 422 and 426 are interposed by an adhesive layer 416 and an insulative layer 418, that may be substantially similar to the solder balls 106 and 108, the adhesive layer 102, and the insulative layer 104 of the solder ball interconnect 100 depicted in FIG. 1a.

The substrate 402 may be rigid or flexible and may include multiple layers of insulative material and conductive interconnects. The substrate 402 may include a PCB, and in some embodiments may include a die pad of a lead frame assembly that may be molded with epoxy, and processed to form a package consisting of the microelectronic device package 400. In another embodiment, the substrate 402 may include another microelectronic device package substrate.

The substrates 404 and 406 may be rigid or flexible and may include polyimide, acrylics, plastic, glass, ceramic, or other materials. The substrates 404 and 406 also include conductive lines for providing electrical connection to the BGA 404a, and the solder balls 422 and 426. The substrates 404 and 406 further include package bond pads 420 and 424 connected to the solder balls 422 and 426, and bond pads 404b, 406a, and 406b for connection to die 408, 410, 412, and 414. The ball grid array 404a may include solder-based materials consisting of lead, tin, silver, copper, or gold. The BGA 404a may be formed by ball bumping or by stud bumping, for example. The die 408, 410, 412, and 414 include a semiconductor material such as silicon processed by multiple steps to form a microelectronic device. In an embodiment, the die 408, 410, 412, and 414 may include an integrated circuit having a myriad of N-type and P-type metal oxide semiconductor (MOS) devices.

The die 408 and 410 are disposed over the substrate 404 with a BGA 408a. The BGA 408a may be formed by gold or copper stud bumping and may be attached to the die 408. The die 410 may be disposed over the die 408, and may include the bond pads 410a attached with wires 410b to the bond pads 404b. In an embodiment, the die 410 may be positioned over the die 408 in a number of different configurations. For example, the die 410 and 408 may include a “pyramid” configuration, wherein the die size of the die 410 is smaller than the die 408. Alternatively, the die 410 may be staggered over the die 408 in an “overhang” configuration. The die 410 and 408 may include a thickness from 10 microns to 500 microns. The die 410 may be connected to the die 408 by wire bonding or solder ball bumping. In an embodiment, the die 410 may be electrically isolated from the die 408, with the exception of electrical continuity provided by the wires 410b, the bond pads 404b, and the substrate 404. The wires 410b may include may include gold, aluminum, or copper. Between the substrates 404 and 406 may be an optional epoxy laminate or underfill 413 to provide electrical isolation and adhesive of the microelectronic device packages 401 and 403. The die 408 and 410, the wires 410b, and bond pads 404b may be encapsulated with an epoxy mold 411 formed by thermal compression, for example. The mold 411 may include epoxy resins, phenolic hardeners, silicas, catalysts, pigments, mold release agents, or other materials.

The die 412 and 414 are disposed over the substrate 406 and connected to the substrate 406 by the wires 412b, 414b, and 414c. The die 414 may be disposed over the die 412, and may include the bond pads 414a connected by the wires 414b and 414c to bond pads 412a and 406a. The die 412 may be connected to the bond pad 406b by wires 412b. In an embodiment, the die 414 may be positioned over the die 412 in a number of different configurations. For example, the die 414 and 412 may include a “pyramid” configuration, wherein the die size of the die 414 is smaller than the die 412. Alternatively, the die 414 may be staggered over the die 412 in an “overhang” configuration. The die 412 and 414 may include a thickness from 10 microns to 500 microns. The wires 412b, 414b, and 414c may include may include gold, aluminum, or copper. Between the die 412 and 414 may be an optional epoxy laminate to provide electrical isolation and adhesion of the die 408 and 410. The die 412 and 414, the wires 412b, 414b, and 414c, and bond pads 412a, 414a, 406a, and 406b, and substrate 406 may be encapsulated with an epoxy mold 415 formed by thermal compression, for example. The mold 415 may include epoxy resins, phenolic hardeners, silicas, catalysts, pigments, mold release agents, or other materials.

In an embodiment, the die 408, 410, 412, and 414 may be operable for providing telecommunication or multimedia services. For example, the die 408 and 410 may include devices operable for processing multi-media content, such as video, sound, and music. The die 408 and 410 may include devices that manage the operation according to the specific type of multi-media to be processed, and may electrically turn on and off portions of the device to reduce operational voltage requirements, for example. The die 412 and 414 may include memory-based devices such as DRAM, SRAM, flash memory, or other memory devices. The die 412 and 414 may store information such as multi-media content that may be processed by the die 408 and 410.

Turning now to FIG. 4b, illustrated is a microelectronic device package 405 disposed over the substrate 402. The microelectronic device package 405 includes a stack or POP configuration of microelectronic device packages 405a and 405b. The package 405a includes the package substrate 404 attached to the substrate 402 by a ball grid array (BGA) 404a. The package 405b includes the package substrate 406 attached to the substrate 404 by stacked solder balls 422 and 426. In an embodiment, the solder balls 422 and 426 are interposed by adhesive layers 416a, 416b, 416c, and 416d and insulative layers 418a and 418b, that may be substantially similar to the solder balls 106 and 108, the adhesive layers 102b and 102c, the optional adhesive layers 107b and 107c, and the insulative layers 104b and 104c of the solder ball interconnect 112 depicted in FIG. 1c. The package 405a includes the die 408 attached to the package substrate 404 by the BGA 408a. The package 405b includes the die 414 attached to the package substrate 406 by the BGA 414a. Between the die 408 and 414 and the package substrates 404 and 406 the underfill 413 provides electrical isolation and adhesion of the die 408 and 414. The die 408 and 414, the package substrates 404 and 406, and the BGA 404a may be encapsulated with an epoxy mold (not shown) formed by thermal compression, for example. The mold may include epoxy resins, phenolic hardeners, silicas, catalysts, pigments, mold release agents, or other materials.

Turning now to FIG. 4c, illustrated is a microelectronic device package 407 disposed over the substrate 402. The microelectronic device package 407 includes an embedded package configuration of die 408. The die 408 is attached to the package substrate 404 that is attached to the substrate 402 by the ball grid array (BGA) 404a. The package 407 includes the package substrate 406 attached to the substrate 404 by stacked solder balls 422 and 426. Like the microelectronic device package 400 of FIG. 4a, the solder balls 422 and 426 are interposed by the adhesive layer 416 and the insulative layer 418, that may be substantially similar to the solder balls 106 and 108, the adhesive layer 102, and the insulative layer 104 of the solder ball interconnect 100 depicted in FIG. 1a. Between the substrates 404 and 406 the underfill 413 provides electrical isolation and protection for the die 408.

In an embodiment, the die 408 and 414 may be operable for providing telecommunication or multimedia services. For example, the die 408 may include devices operable for processing multi-media content, such as video, sound, and music. The die 414 may include devices that manage the operation according to the specific type of multi-media to be processed, and may electrically turn on and off portions of the device to reduce operational voltage requirements, for example. Of course it is to be understood that the die 408 and 414 may include multiple stacked die that may also include memory-based devices such as DRAM, SRAM, flash memory, or other memory devices.

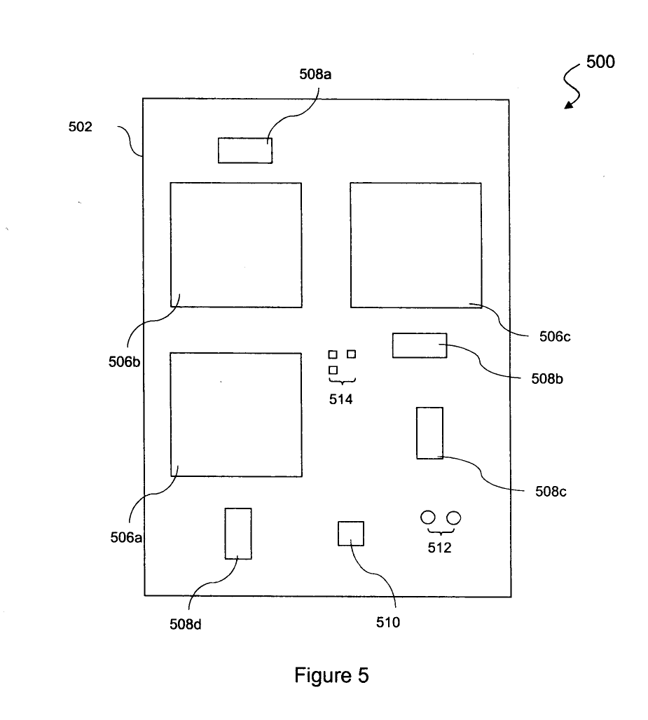

The solder ball interconnect 100, 110, 112, and the interconnects 114 and 118, and the microelectronic device packages 400, 405, and 407 described above may be employed on any general-purpose substrate having electrical contacts and interconnects suitable for integrating a myriad of electronic devices and components. FIG. 5 illustrates a typical, general-purpose PCB 500 suitable for implementing one or more embodiments disclosed herein. The PCB 500 includes a substrate 502, packaged devices 506a, 506b, 506c, 508a, 508b, 508c, 508d, and 510, and electrical components 512, and 514. The substrate 502 may be rigid or flexible and may include multiple layers of insulative material and conductive interconnects. The packaged devices 506a, 506b, 506c, 508a, 508b, 508c, 508d, and 510 may include one or more of the solder ball interconnects 100, 110, 112, or interconnects 114 and 118 of FIGS. 1a-e that are attached to the substrate 502. In some embodiments, the packaged devices 506a, 506b, and 506c may include embedded packages or POP packages, the packaged devices 508a, 508b, 508c, and 508d may include other surface mount type packages, and the packaged device 510 may include a BGA packaged device. The substrate 502 may also include the electrical components 514 in the form of resistors, and the components 512 may include capacitors. The electrical components 514 may also include other components such as inductors, thyristors or fuses (i.e., over-current or over-voltage protection devices), or other small component devices.

In an embodiment, the PCB 500 may be employed in, for example, a mobile electronic device such as a mobile phone or personnel data assistant (PDA). In other embodiments, the PCB 500 may be employed in electrical components employed in automotive vehicles where the PCB 500 may be subjected to a significant amount of thermal stress. The solder ball interconnects 100, 110, 112, or interconnects 114 and 118, and processes 200, 214, and 215 provide a reliable interconnect or joint between or inside of the packaged devices 506a, 506b, 506c, 508a, 508b, 508c, 508d, and 510 and the substrate 502, and therefore provide a reliable product able to withstand significant thermal stress. Of course, the PCB 500 or the microelectronic device package 400, 405, or 407 may be employed in other electronic device packages that may be employed in computers, networking equipment such as wireless routers, mobile audio devices, or other devices.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

Also, techniques, systems, subsystems and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A microelectronic device package interconnect for electrically connecting a plurality of substrates, comprising:
an insulative layer positioned on a substrate, the insulative layer having an opening extending through the insulative layer to the substrate; and
solder positioned in the opening.

2. The microelectronic device package interconnect of claim 1, further comprising an adhesive layer between the insulative layer and the substrate.

3. The microelectronic device package interconnect of claim 2, further comprising a second adhesive layer disposed over the insulative layer, the second adhesive layer having the opening extending through the second adhesive layer, the insulative layer, and the adhesive layer.

4. The microelectronic device package interconnect of claim 2, further comprising a second insulative layer disposed over the insulative layer, the second insulative layer having the opening extending through the second insulative layer, the insulative layer, and the adhesive layer.

5. The microelectronic device package interconnect of claim 1, wherein the solder comprises a stack of a plurality of solder balls.

6. The microelectronic device package interconnect of claim 5, wherein the solder ball has a diameter from 25 microns to 800 microns.

7. The microelectronic device package interconnect of claim 5, wherein the opening retains the solder balls in an alignment substantially perpendicular to the substrate.

8. The microelectronic device package interconnect of claim 5, wherein the thickness of the insulative layer is substantially equal to the height of the stacked solder balls.

9. The microelectronic device package interconnect of claim 1, wherein the solder comprises reflowed solder paste.

10. The microelectronic device package interconnect of claim 1, wherein the insulative layer comprises a thickness from 25 microns to 500 microns.

11. The microelectronic device package interconnect of claim 1, wherein the opening comprises a diameter from 25 microns to 800 microns.

12. The microelectronic device package interconnect of claim 1, wherein the opening comprises:
a first opening having a diameter of 25 microns to 200 microns, and
a second opening having a diameter of 200 microns to 800 microns.

13. A method for manufacturing a microelectronic device package interconnect, comprising:
laminating an insulative layer onto a substrate, the insulative layer having a plurality of openings extending through the insulative layer; and
placing solder into the openings of the insulative layer.

14. The method of claim 13, further comprising:
attaching the insulative layer to a first microelectronic device package, and placing a first solder into the openings of the insulative layer;
providing a second microelectronic device package having a second solder; and
attaching the first solder to the second solder.

15. The method of claim 13, further comprising:
attaching the insulative layer to a first microelectronic device package, and placing the solder into the openings of the insulative layer;
providing a second microelectronic device package having interconnect sites; and
attaching the solder to the interconnect sites.

16. The method of claim 13, further comprising:
attaching the insulative layer to a first microelectronic device package, and placing a first solder into the openings of the insulative layer;
providing a second microelectronic device package having a second solder, and a a second insulative layer; and
attaching the first solder to the second solder.

17. The method of claim 13, wherein the openings are aligned with electrical connections on the substrate.

18. The method of claim 17, further comprising:
reflowing the solder, wherein the insulative layer separates the solder associated with each interconnect site.

19. A printed circuit board (PCB) comprising:
a substrate having a plurality of electrical contact sites;
a microelectronic device package disposed over the electrical contact sites;
an insulative layer positioned between the substrate and the package, the insulative layer having an opening; and
a solder positioned in the opening and electrically coupling the substrate to the microelectronic device package.

20. The PCB of claim 19, wherein the microelectronic device package has a plurality of contacts and the insulative layer has a plurality of openings, and wherein the insulative layer keeps the electrical contact sites, the openings, and the electrical contacts substantially in alignment with each other.

21. The PCB of claim 19, wherein the insulative layer separates the substrate from the microelectronic device package.

22. The PCB of claim 19, further comprising:
a second microelectronic device package attached to one of the microelectronic device package and the substrate, and positioned between the microelectronic device package and the substrate, wherein the insulative layer prevents the second microelectronic device package from contacting both the substrate and the microelectronic device package.
